(19) United States
(12) Patent Application Publication
(10) Pub. No.: US 2026/0035780 A1
(43) Pub. Date: Feb. 5, 2026

(54) DEPOSITION DEVICE FOR DISPLAY DEVICE AND METHOD OF REPLACING MAGNET PLATE OF THE DEPOSITION DEVICE

(71) Applicants: Samsung Display Co., LTD., Yongin-si (KR); ULVAC, INC., Kanagawa (JP)

(72) Inventors: Kyung Hoon CHUNG, Yongin-si (KR); Junichiro KOIKE, Kanagawa (JP); Shuji SHIMIZU, Kanagawa (JP); Kazuhiko KOIZUMI, Kanagawa (JP); Jung Seob LEE, Yongin-si (KR); Yong Sic JEON, Yongin-si (KR); Hyeon Sik KIM, Yongin-si (KR); Yong YEO, Yongin-si (KR)

(21) Appl. No.: 19/176,535

(22) Filed: Apr. 11, 2025

(30) Foreign Application Priority Data
Jul. 31, 2024 (KR) 10-2024-0101619

(51) Int. Cl. C23C 14/50; C23C 14/04; H01L 21/677; H10K 71/16

(52) U.S. Cl. CPC C23C 14/50; C23C 14/042; H01L 21/67748; H10K 71/164

(57) ABSTRACT

Embodiments relates to a deposition device for a display device and a method of replacing a magnet plate of the deposition device. The deposition device includes: a chamber, a deposition source in the chamber; a stage on the deposition source; a mask structure on the stage; a magnet plate on the mask structure; and a first driving mechanism connected to the magnet plate, where the magnet plate is detachably connected to the first driving mechanism.

This application claims priority to Korean Patent Application No. 10-2024-0101619, filed on Jul. 31, 2024, and all the benefits accruing therefrom under 35 U.S.C. § 119, the content of which in its entirety is herein incorporated by reference.

### BACKGROUND

### 1. Field

An embodiment relates to a deposition device for a display device, and more particularly, to a deposition device for a display device, which can improve the adhesion between a mask and a substrate, and a method of replacing a magnet plate of the deposition device.

### 2. Description of the Related Art

Organic light emitting diode displays have self-luminous characteristics and, unlike liquid crystal displays, do not require a separate light source and thus can be reduced in thickness and weight. In addition, organic light emitting diode displays are attracting attention as next-generation displays for portable electronic devices due to their high-quality characteristics such as low power consumption, high luminance, and high response speed.

### SUMMARY

Aspects of the present disclosure provide a deposition device for a display device, which can improve the adhesion between a mask and a substrate, and a method of replacing a magnet plate of the deposition device.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a deposition device for a display device. The deposition device includes: a chamber; a deposition source in the chamber; a stage on the deposition source; a mask structure on the stage; a magnet plate on the mask structure; and a first driving mechanism connected to the magnet plate, wherein the magnet plate is detachably connected to the first driving mechanism.

According to another aspect of the present disclosure, there is provided a method of replacing a magnet plate of a deposition device for a display device. The method includes: loading a first carrier into a chamber of the deposition device by moving the first carrier along a transport track of the deposition device, where the first carriers includes support members; lowering the first carrier by pressing the first carrier with a pusher disposed on the transport track; placing a first magnet plate attached to a driving mechanism of the deposition device in an opening of the first carrier; raising the first carrier by moving the pusher to an original position to support the first magnet plate and load the first magnet plate onto the first carrier; separating the first magnet plate loaded on the first carrier from the driving mechanism; unloading the first carrier loaded with the first magnet plate from the chamber by moving the first carrier along the transport track; loading a second carrier loaded with a second magnet plate into the chamber by moving the second carrier along the transport track; attaching the driving mechanism and the second magnet plate to each other; releasing a constraining force of support members of the second carrier applied to the second magnet plate by lowering the second carrier by pressing the second carrier with the pusher; separating the second magnet plate from the second carrier by moving the driving mechanism to which the second magnet plate is attached; and unloading the second carrier from the chamber by moving the second carrier along the transport track.

According to a deposition device for a display device and a method of replacing a magnet plate of the deposition device according to an embodiment, the adhesion between a mask and a substrate can be effectively improved.

In addition, according to an embodiment, a magnet plate can be easily replaced through a carrier.

The effects of the present disclosure are not limited to the above-described effects and other effects which are not described herein will become apparent to those skilled in the art from the following description.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic diagram of a deposition device according to an embodiment;

FIG. 2 is a plan view of a first surface of a magnet plate of FIG. 1;

FIG. 3 is a plan view of a second surface of the magnet plate of FIG. 1;

FIG. 4 is a perspective view of a carrier disposed on a transport track;

FIG. 5 is an enlarged view of area A1 of FIG. 4;

FIG. 6 is a view for explaining the coupling of the magnet plate to the carrier of FIG. 4;

FIG. 7 is an enlarged view of area A2 of FIG. 6;

FIGS. 8 and 9 are views for explaining the separation of the carrier from the magnet plate; and

FIGS. 10, 11, 12, and 13 are views for explaining a method of replacing the magnet plate of the deposition device according to the embodiment.

FIG. 14 is a block diagram of an electronic device according to one embodiment.

FIGS. 15, 16 and 17 are schematic diagrams of electronic devices according to various embodiments.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, specific exemplary embodiments will be described with reference to the accompanying drawings.

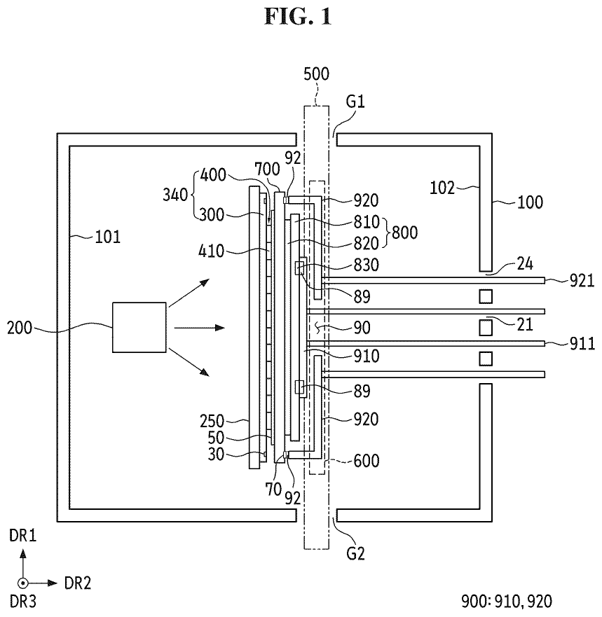

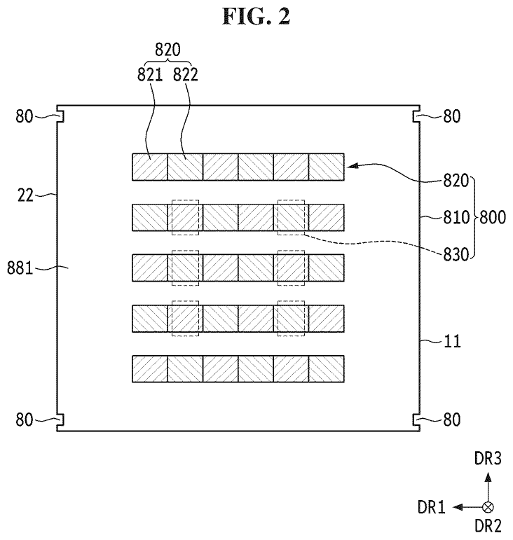

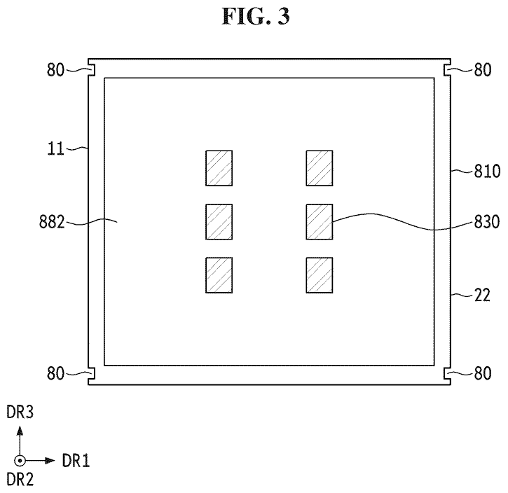

FIG. 1 is a schematic diagram of a deposition device according to an embodiment. FIG. 2 is a plan view of a first surface 881 of a magnet plate 800 of FIG. 1. FIG. 3 is a plan view of a second surface 882 of the magnet plate 800 of FIG. 1. In FIGS. 1 through 3, a direction (hereinafter, referred to as a “third reverse direction”) opposite to a third direction DR3 may be the direction of gravity.

The deposition device for a display device according to the embodiment may include a chamber 100, a deposition source 200, a stage 250, a mask structure 340, a substrate tray 700, the magnet plate 800, a transport track 500, a carrier 600, and a driving mechanism 900 as illustrated in FIG. 1.

The chamber 100 may define a deposition space in which a deposition process is performed. A layer deposition process for manufacturing an organic light emitting diode display device may be performed inside the chamber 100. The chamber 100 may be a vacuum chamber 100. The deposition source 200, the stage 250, the driving mechanism 900, and a portion of the transport track 500 described above may be disposed inside the chamber 100. When a deposition process is in progress, the deposition source 200, the stage 250, the mask structure 340, a substrate 50, the substrate tray 700, the magnet plate 800, a portion of the transport track 500, and the driving mechanism 900 may be disposed inside the chamber 100.

The deposition source 200 may be disposed inside the chamber 100. For example, the deposition source 200 may be disposed between a first inner wall 101 of the chamber 100 and the stage 250. The deposition source 200 may provide a deposition material. The deposition material from the deposition source 200 may pass through an opening of the stage 250 and move toward the mask structure 340. Specifically, the deposition source 200 may evaporate a deposition material such as an organic material or an electrode material by heating the deposition material to a high temperature, and the evaporated deposition material may be deposited on the substrate 50 through pattern holes of the mask structure 340. The organic material may be, for example, a material for manufacturing a hole injection layer, a hole transport layer, a light emitting layer, an electron transport layer, and an electron injection layer disposed between an anode and a cathode of an organic light emitting diode. The substrate 50 may be, for example, a substrate used in a display device including organic light emitting diodes.

The stage 250 may be disposed on the deposition source 200. For example, the stage 250 may be disposed between the deposition source 200 and the mask structure 340. The stage 250 may be disposed in a fixed state inside the chamber 100. The stage 250 may be tilted toward the deposition source 200. For example, the stage 250 may be tilted in a direction (hereinafter, referred to as a “second reverse direction”) opposite to a second direction DR2 with respect to the third direction DR3. Accordingly, an angle formed between a surface of the stage 250 which faces the deposition source 200 and the ground (e.g., a bottom surface of the chamber 100) on which the stage 250 is disposed may be an acute angle. Here, supports may be disposed on a lower side of the stage 250 to protrude from a surface of the lower side. The stage 250 may be shaped like a quadrangular frame with a penetrated central portion. For example, the stage 250 may define an opening in the central portion thereof.

The mask structure 340 may be disposed on the stage 250. For example, the mask structure 340 may be disposed between the stage 250 and the substrate tray 700. The mask structure 340 may be disposed on the supports of the stage 250. Here, since the stage 250 is tilted, the mask structure 340 may also be tilted on the stage 250. The mask structure 340 may include a frame 300 and a mask 400.

The frame 300 may be disposed on the stage 250. For example, the frame 300 may be disposed between the stage 250 and the mask 400. The frame 300 may be shaped like a quadrangular frame with a penetrated central portion. For example, the frame 300 may define an opening in the central portion thereof. Grooves 30 may be defined at two opposite sides of the frame 300. The frame 300 may include a magnetic material. For example, the frame 300 may include a material (e.g., iron (Fe)) that can be attracted to a magnet.

The mask 400 may be disposed on the frame 300. For example, the mask 400 may be disposed between the frame 300 and the substrate tray 700. The mask 400 may be disposed on the frame 300 to cover the opening of the frame 300. Edges of the mask 400 may be attached to the frame 300. For example, the mask 400 may be attached to the frame 300 by welding. The mask 400 may be a fine metal mask (FMM).

The mask 400 may include a plurality of sub-masks 410 (or mask sticks). Each of the sub-masks 410 may have a rectangular shape extending in the third direction DR3. The sub-masks 410 may be arranged along a first direction DR1. Adjacent sub-masks 410 may contact each other. Each sub-mask 410 excluding two opposite edges may be disposed on the opening of the frame 300. Although not illustrated, each sub-mask 410 may defines a plurality of pattern holes penetrating the sub-mask 410 in the second direction DR2. A deposition material from the deposition source 200 may be deposited on the substrate 50 through the pattern holes of each sub-mask 410. Each sub-mask 410 may be made of a material including a magnetic material (e.g., iron (Fe)). For example, each sub-mask 410 may include a material that is attracted to a magnet.

The substrate tray 700 may be disposed on the mask structure 340. For example, the substrate tray 700 may be disposed between the mask 400 of the mask structure 340 and the magnet plate 800. The substrate tray 700 may transport the substrate 50. Here, the substrate tray 700 may adsorb the substrate 50 using an electrostatic force. For example, the substrate tray 700 may provide a surface on which the substrate 50 is placed while serving as an electrostatic chuck which adsorbs and fixes the substrate 50 to the surface of the substrate tray 700. The substrate tray 700 may be made of a material including ceramic or titanium.

The magnet plate 800 may be disposed on the substrate tray 700. For example, the magnet plate 800 may be disposed between the substrate tray 700 and the driving mechanism 900. The magnet plate 800 may be disposed on the substrate tray 700 to face the substrate tray 700. The magnet plate 800 may provide a magnetic force. For example, the magnet plate 800 may provide a magnetic force so that the metal mask 400 described above is closely attached to the substrate 50.

The magnet plate 800 may include a base member 810 and a plurality of magnets 820 disposed on the base member 810. For example, the magnets 820 may be disposed on the base member 810. As a specific example, when a side surface of the base member 810 which faces the substrate tray 700 is defined as the first surface 881, the magnets 820 may be disposed on the first surface 881 of the base member 810. Each magnet 820 may include, for example, a permanent magnet.

Each of the magnets 820 may have an N pole and an S pole. A plurality of magnets 820 disposed along the first direction DRI may be disposed such that opposite polarities face each other in the first direction DR1. A plurality of magnets 820 disposed along the second direction DR2 may be disposed such that opposite polarities face each other.

When a surface opposite the first surface 881 of the base member 810 is defined as the second surface 882 of the base member 810, a plurality of magnetic objects 830 may be disposed on the second surface 882 of the base member 810. For example, the magnetic objects 830 may be disposed on the second surface 882 in coupling grooves of the base member 810. For example, the magnetic objects 830 may include a material (e.g., iron (Fe)) that can be attracted to a magnet.

At least one groove 80 may be defined at two opposite sides of the base member 810. For example, as illustrated in FIGS. 2 and 3, a groove 80 may be defined near each corner of the quadrangular base member 810. Specifically, the base member 810 may have four grooves 80. Here, two of the four grooves 80 may be defined at the top and bottom of a first side 11 of the base member 810, respectively, and the remaining two grooves 80 may be defined at the top and bottom of a second side 22 of the base member 810, respectively. The first side 11 and the second side 22 of the base member 810 may face each other. Grooves 80 defined on different sides and facing each other may be recessed toward each other.

The driving mechanism 900 may include a first driving mechanism 910 and a second driving mechanism 920.

The first driving mechanism 910 may be disposed between the magnet plate 800 and the second driving mechanism 920. For example, the first driving mechanism 910 may be disposed between the base member 810 of the magnet plate 800 and the second driving mechanism 920. The first driving mechanism 910 may include magnets 89. For example, the magnets 89 may be disposed on a surface opposite a surface of the first driving mechanism 910 which is connected to a first driving shaft 911. The magnets 89 of the first driving mechanism 910 may correspond to (or overlap) the magnetic objects 830 of the magnet plate 800. The magnets 89 may include permanent magnets.

The magnet plate 800 may be detachably attached to the first driving mechanism 910. For example, the base member 810 of the magnet plate 800 may be detachably attached to the magnets 89 of the first driving mechanism 910. In other words, the magnetic objects 830 of the base member 810 may be attached to the magnets 89 of the first driving mechanism 910 by a magnetic force from the magnets 89 of the first driving mechanism 910. The first driving mechanism 910 may move toward the deposition source 200 or in the opposite direction within the chamber 100. For example, the first driving mechanism 910 may move along the second reverse direction or the second direction DR2. To this end, according to an embodiment, the first driving mechanism 910 may be connected to the first driving shaft 911 which is extended along the second reverse direction or retracted along the second direction DR2. The first driving shaft 911 may be connected to an external driver through a hole 90 of the second driving mechanism 920 and a hole 21 of the chamber 100. In addition, the first driving mechanism 910 may move further in the first direction DR1, a first reverse direction (a direction opposite to the first direction DR1), the third direction DR3, or the third reverse direction. In this case, the first driving shaft 911 may move further in the first direction DR1, the first reverse direction, the third direction DR3, or the third reverse direction. The movement of the magnet plate 800 attached to the first driving mechanism 910 may be controlled by the movement of the first driving mechanism 910.

The second driving mechanism 920 may be disposed between the first driving mechanism 910 and a second inner wall 102 of the chamber 100. The second driving mechanism 920 may include electro-permanent magnets 92. The substrate tray 700 may be attached to the second driving mechanism 920. For example, the substrate tray 700 may be attached to the second driving mechanism 920 as magnetic objects 70 of the substrate tray 700 are attached to the electro-permanent magnets 92 of the second driving mechanism 920. The electro-permanent magnets 92 may be disposed at two opposite edges of the second driving mechanism 920. The magnetic objects 70 may be disposed at two opposite edges of the substrate tray 700 to correspond to the electro-permanent magnets 92. The magnetic objects 70 may include a magnetic material that is attracted to a magnet, such as iron (Fe).

The second driving mechanism 920 may also include electromagnets instead of the electro-permanent magnets 92. The second driving mechanism 920 may move toward the deposition source 200 or in the opposite direction within the chamber 100. For example, the second driving mechanism 920 may move along the second reverse direction or the second direction DR2. To this end, according to an embodiment, the second driving mechanism 920 may be connected to a second driving shaft 921 which is extended along the second reverse direction or retracted along the second direction DR2. In addition, the second driving mechanism 920 may move further in the first direction DR1, the first reverse direction, the third direction DR3, or the third reverse direction. In this case, the second driving shaft 921 may move further in the first direction DR1, the first reverse direction, the third direction DR3, or the third reverse direction. The movement of the substrate tray 700 attached to the second driving mechanism 920 may be controlled by the movement of the second driving mechanism 920. The second driving mechanism 920 may perform an alignment operation between the substrate 50 of the substrate tray 700 and the mask structure 340 by controlling the position of the substrate tray 700 attached to the second driving mechanism 920.

The transport track 500 may be, for example, disposed inside the chamber 100 and outside the chamber 100 to pass through a first gate G1 and a second gate G2 of the chamber 100. The transport track 500 may extend along the first direction DR1. The first gate G1 and the second gate G2 may face each other.

The carrier 600 may move along the transport track 500. For example, the carrier 600 may move along the transport track 500 in a magnetic levitation manner. The carrier 600 may transport the magnet plate 800.

As described above, an upper side of the stage 250 may be tilted toward the deposition source 200. Accordingly, the mask structure 340, the substrate tray 700, the substrate 50, the magnet plate 800, the first driving mechanism 910, the second driving mechanism 920, the tran sport track 500, and the carrier 600 described above may also be tilted at the same angle as the stage 250. Accordingly, particles generated during a deposition process on the substrate 50 may fall in the direction of gravity without sticking to the substrate 50. Therefore, the substrate 50 can be prevented from being contaminated by the particles.

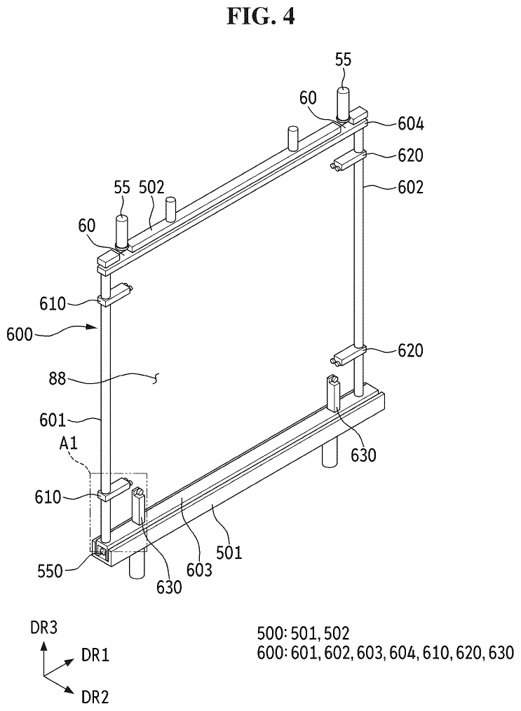

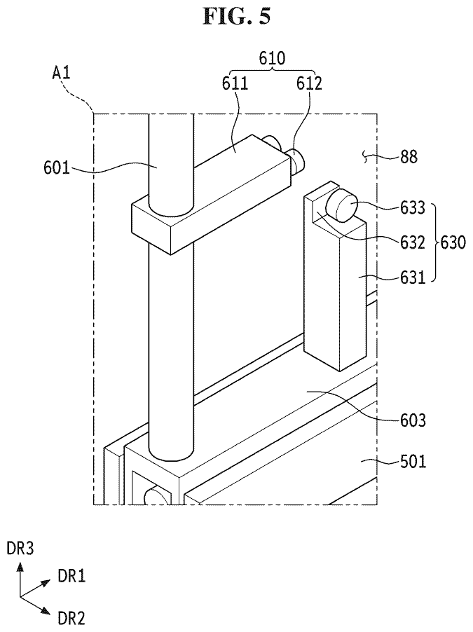

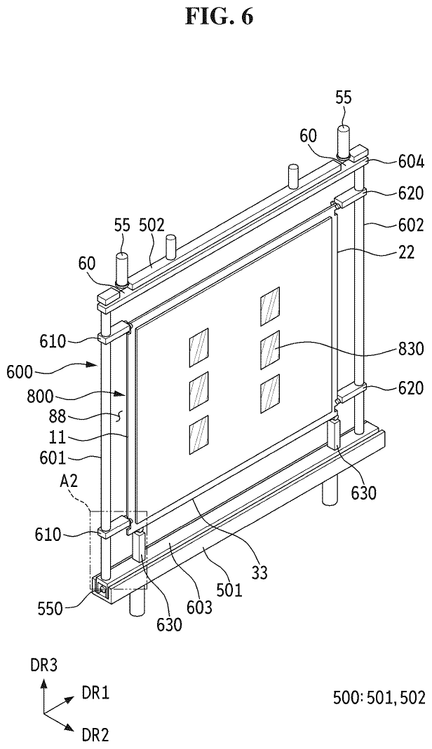

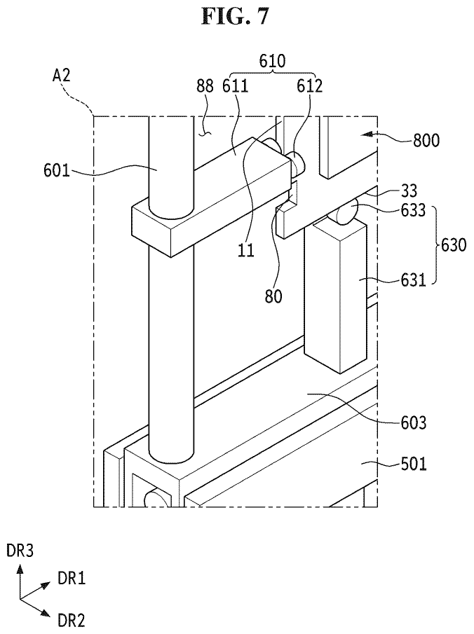

FIG. 4 is a perspective view of the carrier 600 disposed on the transport track 500. FIG. 5 is an enlarged view of area A1 of FIG. 4. FIG. 6 is a view for explaining the coupling of the magnet plate 800 to the carrier 600 of FIG. 4. FIG. 7 is an enlarged view of area A2 of FIG. 6. Here, FIG. 4 may be a perspective view of the carrier 600 disposed on the transport track 500 of FIG. 1.

The carrier 600 may move along the transport track 500. The transport track 500 may include a lower track 501 and an upper track 502 facing each other in the third direction DR3. The lower track 501 may have a U-shaped cross section, and the upper track 502 may have a bar shape. The carrier 600 may be disposed between the lower track 501 and the upper track 502. The carrier 600 may move along the transport track 500 between the lower track 501 and the upper track 502.

The carrier 600 may be shaped like a quadrangular frame as in the example illustrated in FIG. 4. However, the shape of the carrier 600 is not limited thereto and can be changed to various shapes.

The carrier 600 may include a plurality of bars 601, 602, 603 and 604 and a plurality of support members 610, 620 and 630. For example, the carrier 600 may include a first bar 601, a second bar 602, a third bar 603, and a fourth bar 604 connected to each other. The magnet plate 800 may be placed in an area (e.g., an opening 88) surrounded and defined by the first bar 601, the second bar 602, the third bar 603, and the fourth bar 604. Here, the third bar 603 may have a U-shaped cross section.

The first bar 601 and the second bar 602 may face each other in the first direction DR1. The third bar 603 and the fourth bar 604 may face each other in the third direction DR3. The first bar 601 may be disposed between an end of the third bar 603 and an end of the fourth bar 604. The second bar 602 may be disposed between the other end of the third bar 603 and the other end of the fourth bar 604.

The support members 610, 620 and 630 may include one or more first support members 610 extending from the first bar 601, one or more second support members 620 extending from the second bar 602, and one or more third support members 630 extending from the third bar 603. For example, two first support members 610 may extend from a side and the other side of the first bar 601 toward the second bar 602, respectively. For example, the two first support members 610 may extend from a side and the other side of the first bar 601 along the first direction DR1. Two second support members 620 may extend from a side and the other side of the second bar 602 toward the first bar 601, respectively. For example, the two second support members 620 may extend from a side and the other side of the second bar 602 along the first reverse direction, respectively. Two third support members 630 may extend from a side and the other side of the third bar 603 toward the fourth bar 604, respectively. For example, the two third support members 630 may extend from a side and the other side of the third bar 603 along the third direction DR3, respectively. The two first support members 610 and the two second support members 620 may face each other, respectively.

As illustrated in FIG. 5, each of the first support members 610 may include an extension portion 611 and a plurality of protrusions 612. An end portion of the extension portion 611 may be connected to the first bar 601. The extension portion 611 may extend from the first bar 601 toward the second bar 602. The protrusions 612 (e.g., two protrusions 612) may be disposed on the other end portion of the extension portion 611. The protrusions 612 may be rotatably connected to the other side of the extension portion 611. For example, each of the protrusions 612 may rotate along the circumference of a circle in contact with a tangent line extending along the second direction DR2. The protrusions 612 may face each other in the second direction DR2. Each of the protrusions 612 may have a cylindrical shape. However, the shape of the protrusions 612 is not limited thereto and can be changed to various shapes.

The second support members 620 may have the same configuration as the first support members 610 described above. However, an extension portion of each of the second support members 620 may extend from the second bar 602 toward the first bar 601.

Each of the third support members 630 may include an extension portion 631, a protruding portion 632, and a protrusion 633. A side (e.g., an end portion) of the extension portion 631 may be connected to the third bar 603. The extension portion 631 may extend from the third bar 603 toward the fourth bar 604. The protruding portion 632 may be disposed on the other side (e.g., the other end portion) of the extension portion 631. The protrusion 633 may be disposed on a side of the protruding portion 632. The protrusion 633 may be rotatably connected to the side of the protruding portion 632. For example, the protrusion 633 may rotate along the circumference of a circle in contact with a tangent line extending along the first direction DR1. The protrusion 633 may have a cylindrical shape. However, the shape of the protrusion 633 is not limited thereto and can be changed to various shapes.

As illustrated in FIGS. 6 and 7, the first support members 610, the second support members 620, and the third support members 630 may support the magnet plate 800. For example, the first support members 610, the second support members 620, and the third support members 630 may support the base member 810 of the magnet plate 800.

Each of the first support members 610 may support the first side 11 of the base member 810. For example, the first side 11 of the base member 810 may be placed and supported between the protrusions 612 of each first support member 610. In this case, the protrusions 612 of each first support member 610 may contact the first side 11.

Each of the second support members 620 may support the second side 22 of the base member 810. For example, the second side 22 of the base member 810 may be placed and supported between protrusions of each second support member 620. In this case, the protrusions of each second support member 620 may contact the second side 22.

Each of the third support members 630 may support a third side 33 of the base member 810. For example, the third side 33 of the base member 810 may be placed and supported on the protrusion 633 of each third support member 630. In this case, the protrusion 633 of each third support member 630 may contact the third side 33.

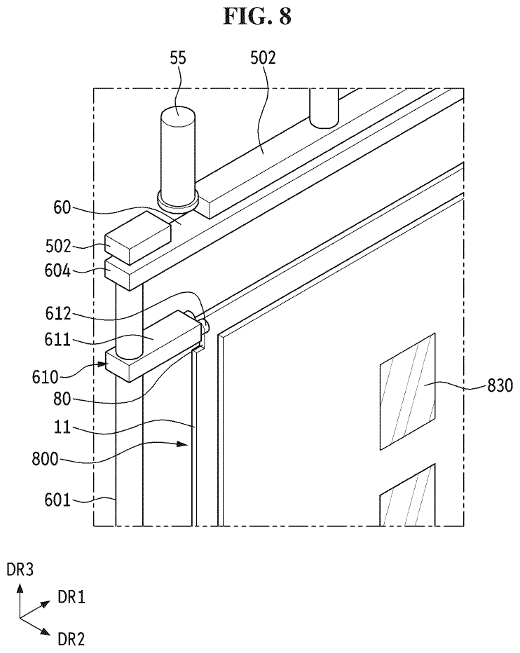

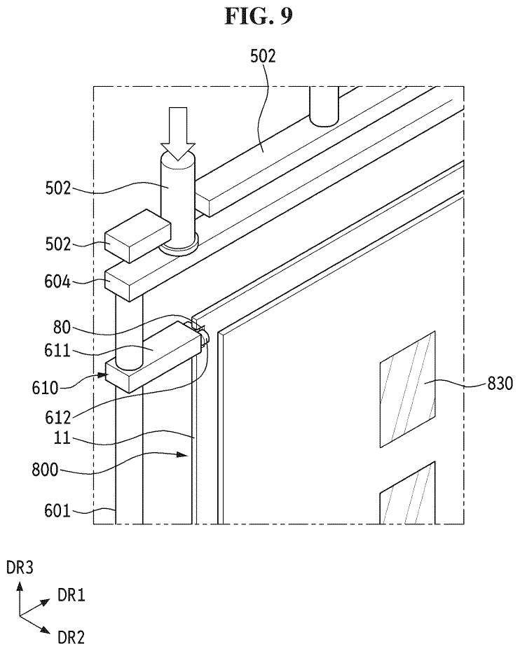

FIGS. 8 and 9 are views for explaining the separation of the carrier 600 from the magnet plate 800.

The deposition device of the embodiment may further include pushers 55. The pushers 55 may be disposed on the carrier 600. For example, as illustrated in FIG. 8, the pushers 55 may be disposed on the fourth bar 604 of the carrier 600. Specifically, the pushers 55 may face the fourth bar 604 through openings 60 of the upper track 502. The pushers 55 and the openings 60 of the upper track 502 may be disposed inside the chamber 100

The pushers 55 may move toward the fourth bar 604 or in the opposite direction. For example, the pushers 55 may move along the third reverse direction or the third direction DR3. The pushers 55 may move a distance of a first stage and a distance of a second stage along the third reverse direction. Here, the distance of the second stage may be greater than the distance of the first stage. Here, when the pushers 55 descend the distance of the second stage along the third reverse direction, the lower track 501 may also descend along the third reverse direction. For example, when the pushers 55 descend the distance of the second stage, the pushers 55 and the lower track 501 may descend together in the same direction.

When the pushers 55 descend the distance of the first stage along the third reverse direction, they may contact the carrier 600. The carrier 600 may be lowered along the third reverse direction by the pressure of the pushers 55. In this case, since the lower track 501 remains as it is without being lowered, a gap between the carrier 600 and the lower track 501 may be reduced. Accordingly, the carrier 600 can be stably placed on the lower track 501 inside the chamber 100. Here, when the pushers 55 descend the distance of the first stage, the descending distance is short. Therefore, even if the carrier 600 is lowered by the pressure of the pushers 55, the magnet plate 800 accommodated in the carrier 600 may be kept supported by the support members 610, 620 and 630 of the carrier 600.

When the pushers 55 descend the distance of the second stage, the lower track 501 may also descend along the third reverse direction at the same time as the pushers 55. In other words, the pushers 55 and the lower track 501 may simultaneously descend along the third reverse direction. Accordingly, the carrier 600 and the lower track 501 may descend along the third reverse direction. In this case, the gap between the carrier 600 and the lower track 501 may be substantially equal to the gap between the carrier 600 and the lower track 501 when the pushers 55 descend the distance of the first stage described above. Accordingly, the first support members 610, the second support members 620, and the third support members 630 may be moved in the third reverse direction. Therefore, the protrusions 612 of each first support member 610 and the protrusions of each second support member 620 may be placed to face each other through the grooves 80 of the magnet plate 800. In other words, the protrusions 612 of each first support member 610 and the first side 11 of the magnet plate 800 do not contact each other, and the protrusions 612 of each second support member 620 and the second side 22 of the magnet plate 800 do not contact each other. In addition, as the carrier 600 is lowered along the third reverse direction by the pushers 55 as described above, the third support members 630 and the magnet plate 800 may be separated from each other. For example, since the protrusions 633 of the third support members 630 and the third side 33 of the magnet plate 800 are separated from each other, the protrusions 633 of the third support members 630 and the third side 33 do not contact each other. Accordingly, the magnet plate 800 is no longer supported by the carrier 600. Therefore, the magnet plate 800 can easily move in the second direction DR2 and the second reverse direction without being interfered with by the carrier 600.

A mover 550 may be disposed inside the lower track 501. The mover 550 may have a screw shape. A plurality of permanent magnets may be disposed on an outer circumferential surface of the mover 550. Permanent magnets may also be disposed on the inside of the lower track 501 and on each of facing surfaces of the upper track 502 and the fourth bar 604 of the carrier 600. By the rotation of these permanent magnets and the mover 550, the carrier 600 may be moved along the transport track 500 in a magnetic levitation manner. For example, the movement direction of the carrier 600 disposed on the transport track 500 may be controlled according to the rotation direction of the mover 550. Specifically, when the mover 550 rotates clockwise, the carrier 600 may move on the transport track 500 along the first direction DR1. On the other hand, when the mover 550 rotates counterclockwise, the carrier 600 may move on the transport track 500 along the first reverse direction.

A deposition method of the deposition device according to the embodiment configured as described above will be described in detail as follows.

First, the deposition source 200, the stage 250, the first driving mechanism 910, and the second driving mechanism 920 may be disposed inside the chamber 100. In this case, the magnet plate 800 may be attached to the first driving mechanism 910. In addition, the first driving mechanism 910 and the second driving mechanism 920 may be disposed between the transport track 500 and the second inner wall 102 of the chamber 100 so as not to overlap the transport track 500.

Next, a first carrier loaded with the mask structure 340 may be loaded into the chamber 100 along the transport track 500. For example, the first carrier loaded with the mask structure 340 may be loaded (or placed) into the chamber 100 through the first gate G1 of the chamber 100 along the transport track 500. The first carrier may be placed inside the chamber 100 such that the mask structure 340 is aligned with the stage 250 between the stage 250 and the driving mechanism 900.

Next, the driving mechanism 900 may move toward the first carrier. In this case, as the electro-permanent magnets 92 of the second driving mechanism 920 and the frame 300 of the mask structure 340 contact each other, the mask structure 340 may be attached to the second driving mechanism 920. For example, the electro-permanent magnets 92 of the second driving mechanism 920 may be inserted into the grooves 30 of the frame 300, and the frame 300 may be attached to the second driving mechanism 920 by a magnetic force from the electro-permanent magnets 92. In other words, the frame 300 of the mask structure 340 and the mask structure 340 in the first carrier may be attached to the second driving mechanism 920.

Next, while the mask structure 340 is attached to the second driving mechanism 920, the pushers 55 may press the first carrier in the third reverse direction. Accordingly, a constraining force of support members of the first carrier applied to the mask structure 340 may be removed. Therefore, the mask structure 340 may be maintained in a state where it can move in the second direction DR2 and the second reverse direction from the first carrier.

Next, the driving mechanism 900 may move further along the second reverse direction. In other words, the driving mechanism 900 may move toward the stage 250. Accordingly, the mask structure 340 attached to the second driving mechanism 920 may be separated from the first carrier in the second reverse direction and moved in the second reverse direction along with the second driving mechanism 920 to leave the transport track 500. Next, the driving mechanism 900 to which the mask structure 340 is attached may move further in the second reverse direction toward the stage 250 to place the mask structure 340 on the stage 250. When the mask structure 340 is placed on the stage 250, the second driving mechanism 920 and the mask structure 340 may be separated from each other. For example, the mask structure 340 may be separated from the second driving mechanism 920 as the magnetic force of the electro-permanent magnets 92 of the second driving mechanism 920 is released.

Next, the driving mechanism 900 may be moved in the second direction DR2. For example, the driving mechanism 900 may pass through an opening of the first carrier along the second direction DR2. Then, the driving mechanism 900 may be placed between the transport track 500 and the second inner wall 102 of the first chamber 100.

Next, the pushers 55 may be raised and moved to the original position. Accordingly, the first carrier (e.g., the empty first carrier) which has transported the mask structure 340 may be raised and moved to the original position. Then, the first carrier (e.g., the empty first carrier) may be unloaded from the chamber 100 through the second gate G2 of the chamber 100 along the transport track 500.

Next, a second carrier loaded with the substrate tray 700 (e.g., the substrate tray 700 on which the substrate 50 is placed) may be loaded into the chamber 100 along the transport track 500. For example, the second carrier loaded with the substrate tray 700 may be loaded (or placed) into the chamber 100 through the first gate G1 of the chamber 100 along the transport track 500. For example, the second carrier may be placed inside the chamber 100 such that the substrate tray 700 is aligned with the mask structure 340 between the mask structure 340 and the driving mechanism 900.

Next, the driving mechanism 900 may move toward the second carrier. In this case, as the electro-permanent magnets 92 of the second driving mechanism 920 and the magnetic objects 70 of the substrate tray 700 contact each other, the substrate tray 700 may be attached to the second driving mechanism 920. For example, the substrate tray 700 may be attached to the second driving mechanism 920 by a magnetic force from the electro-permanent magnets 92.

Next, while the substrate tray 700 is attached to the second driving mechanism 920, the pushers 55 may press the second carrier in the third reverse direction. Accordingly, a constraining force of support members of the second carrier applied to the substrate tray 700 may be removed. Therefore, the substrate tray 700 may be maintained in a state where it can move in the second direction DR2 and the second reverse direction from the second carrier.

Next, the driving mechanism 900 may move further along the second reverse direction. In other words, the driving mechanism 900 may move toward the mask structure 340 on the stage 250. Accordingly, the substrate tray 700 attached to the second driving mechanism 920 may be separated from the second carrier in the second reverse direction and moved in the second reverse direction along with the second driving mechanism 920 to leave the transport track 500. Next, the driving mechanism 900 to which the substrate tray 700 is attached may move further in the second reverse direction toward the mask structure 340 on the stage 250 to place the substrate tray 700 on the mask structure 340.

Next, the first driving mechanism 910 may be moved further along the second reverse direction toward the substrate tray 700. Accordingly, the magnet plate 800 attached to the first driving mechanism 910 may become close to the substrate tray 700 or may contact the substrate tray 700. Then, the mask structure 340 may be attracted toward the magnets 820 of the magnet plate 800 by a magnetic force from the magnet plate 800. Accordingly, the adhesion between the substrate 50 on the substrate tray 700 and the mask structure 340 can be effectively improved.

Next, a deposition material from the deposition source 200 may be deposited on the substrate 50 through the pattern holes of the mask structure 340. For example, a deposition process may be performed on the substrate 50. According to an embodiment, during the deposition process on the substrate 50, since the magnet plate 800 is placed on the substrate tray 700 without being loaded onto the carrier 600, it may be placed closer to the substrate tray 700. In other words, since a thickness of the carrier 600 (e.g., a size of the carrier 600 in the second direction DR2) is greater than a thickness of the magnet plate 800 (e.g., a size of the magnet plate 800 in the second direction DR2), if the magnet plate 800 is placed on the substrate tray 700 in a state where it is separated from the carrier 600 as in the embodiment, the magnet plate 800 can be placed closer to the substrate tray 700. Accordingly, a distance between the mask structure 340 and the magnet plate 800 can be further reduced, thereby further increasing the magnetic force provided from the magnet plate 800 to the mask structure 340. Accordingly, the adhesion between the mask structure 340 and the substrate 50 can be effectively improved. Accordingly, this can further improve the alignment state between the mask 400 of the mask structure 340 and the substrate 50.

When the deposition process on the substrate 50 is completed, the first driving mechanism 910 to which the magnet plate 800 is attached may move along the second direction DR2, thereby weakening the adhesion between the mask structure 340 and the substrate 50.

Next, the driving mechanism 900 may be moved in the second direction DR2. In this case, the substrate tray 700 (e.g., the substrate tray 700 on which the substrate 50 which has gone through the deposition process is placed) attached to the second driving mechanism 920 may also be moved in the second direction DR2. The substrate tray 700 attached to the second driving mechanism 920 may be recoupled (or reloaded) to the second carrier (e.g., the empty second carrier). For example, the substrate tray 700 may be placed in an opening of the second carrier 600 by the movement of the driving mechanism 900. In this case, as the pushers 55 pressing the second carrier 600 ascend along the third direction DR3 and return to the original position, the support members of the second carrier and the substrate tray 700 may contact each other again. Accordingly, the substrate tray 700 (e.g., the substrate tray 700 on which the substrate 50 which has gone through the deposition process is placed) may be recoupled to the second carrier 600. After the substrate tray 700 is recoupled to the second carrier 600, the second driving mechanism 920 and the substrate tray 700 may be separated from each other. For example, the magnetic force of the electro-permanent magnets 92 of the second driving mechanism 920 may be released, thereby separating the second driving mechanism 920 and the substrate tray 700 from each other.

Next, the driving mechanism 900 may be moved further in the second direction DR2. Accordingly, the driving mechanism 900 may be placed between the transport track 500 and the second inner wall 102 of the first chamber 100.

Next, the second carrier loaded with the substrate tray 700 (e.g., the substrate tray 700 on which the substrate 50 which has gone through the deposition process is placed) may be unloaded from the chamber 100 through the second gate G2 of the chamber 100 along the transport track 500.

When the first driving mechanism 910 is moved during the above deposition process, it may be moved together with the second driving mechanism 920. Similarly, when the second driving mechanism 920 is moved during the deposition process, it may be moved together with the first driving mechanism 910. For example, when the first driving mechanism 910 is located on a movement path along which the second driving mechanism 920 is moved, the second driving mechanism 920 and the first driving mechanism 910 may move together. In this case, the first driving mechanism 910 may be moved together with the second driving mechanism 920 while being disposed within the second driving mechanism 920. For example, as illustrated in FIG. 1, the second driving mechanism 920 may have a cross section (e.g., a “]”-shaped cross section) surrounding the first driving mechanism 910. Therefore, the first driving mechanism 910 may be moved together with the second driving mechanism 920 while being disposed within the second driving mechanism 920 and surrounded by the second driving mechanism 920.

Due to aging, damage, or model change of the magnet plate 800, the magnet plate 800 may be replaced with another new magnet plate 800. A method of replacing the magnet plate 800 will be described in detail as follows.

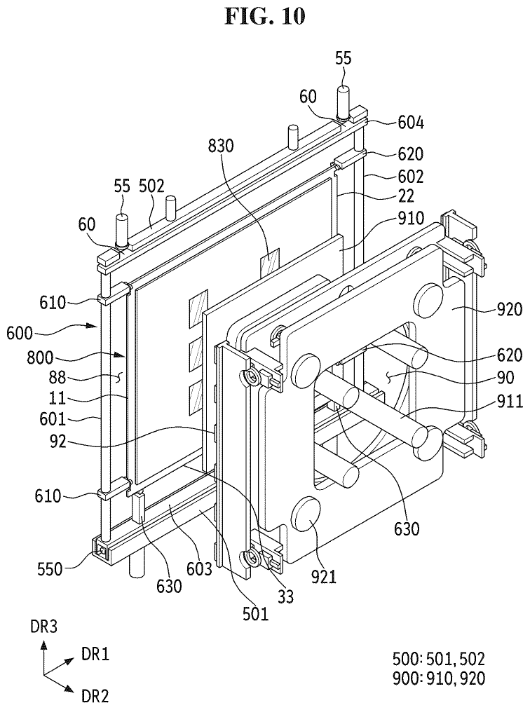

FIGS. 10, 11, 12, and 13 are views for explaining a method of replacing the magnet plate 800 of the deposition device according to the embodiment.

First, although not illustrated, an empty carrier (hereinafter, referred to as a third carrier (e.g., 600)) may be loaded into the chamber 100 along the transport track 500. In other words, the third carrier not loaded with anything inside may be loaded into the chamber 100. In this case, the driving mechanism 900 inside the chamber 100 may be placed between the transport track 500 and the second inner wall 102 of the chamber 100.

Next, the pushers 55 may press the third carrier along the third reverse direction. For example, the pushers 55 may descend the distance of the first stage to press the third carrier. Accordingly, the third carrier 600 can be stably placed on the transport track 500 inside the chamber 100.

Next, in a state where the lower track 501 is lowered and the third carrier 600 is also lowered (e.g., lowered to the distance of the second stage) by the pushers 55, the first driving mechanism 910 to which a magnet plate to be replaced (hereinafter, referred to as a first magnet plate) is attached may move toward the third carrier along the second reverse direction to place the first magnet plate in an opening (e.g., 88) of the third carrier. In this case, since support members of the third carrier have been lowered by the pushers 55, when the first magnet plate moves to the opening of the third carrier along the second reverse direction, the support members of the third carrier may pass through grooves (e.g., 80) of the first magnet plate. Therefore, the first magnet plate can be moved in the second reverse direction without being interfered with by the support members and then can be placed in the opening of the third carrier.

Next, as the pushers 55 are raised along the third direction DR3 and moved to the original position, the pressure of the pushers 55 applied to the third carrier may be released. Accordingly, the third carrier may ascend along the third direction DR3. In other words, the third carrier may move to the original position. Accordingly, the support members of the third carrier may move to the original position. Then, the support members of the third carrier and the first magnet plate in the third carrier may contact each other. Accordingly, the first magnet plate may be supported by the support members. For example, the first magnet plate may be loaded onto the third carrier.

Next, with the first magnet plate loaded onto the third carrier, the first driving mechanism 910 may move along the second direction DR2. Accordingly, the first magnet plate may be separated from the first driving mechanism 910.

Next, the third carrier loaded with the first magnet plate may be unloaded from the chamber 100 through the second gate G2 along the transport track 500.

Next, as illustrated in FIG. 10, a carrier 600 (hereinafter, referred to as a fourth carrier 600) loaded with a new magnet plate 800 (hereinafter, referred to as a second magnet plate 800) may be loaded into the chamber 100 along the transport track 500. For example, the fourth carrier 600 loaded with the second magnet plate 800 may be loaded (or placed) into the chamber 100 through the first gate G1 of the chamber 100 along the transport track 500. In this case, the driving mechanism 900 inside the chamber 100 may be placed between the transport track 500 and the second inner wall 102 of the chamber 100.

Next, the pushers 55 may press the fourth carrier 600 along the third reverse direction. For example, the pushers 55 may descend the distance of the first stage to press the fourth carrier 600. Accordingly, the fourth carrier 600 can be stably placed on the transport track 500 inside the chamber 100.

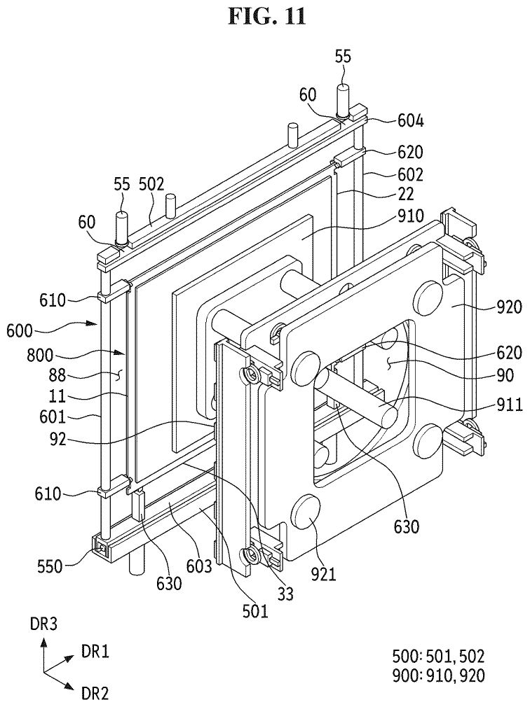

Next, as illustrated in FIG. 11, the first driving mechanism 910 placed between the transport track 500 and the second inner wall 102 of the chamber 100 may move toward the fourth carrier 600 and contact the second magnet plate 800 within the fourth carrier 600. Then, the second magnet plate 800 may be attached to the first driving mechanism 910 by a magnetic force from the first driving mechanism 910.

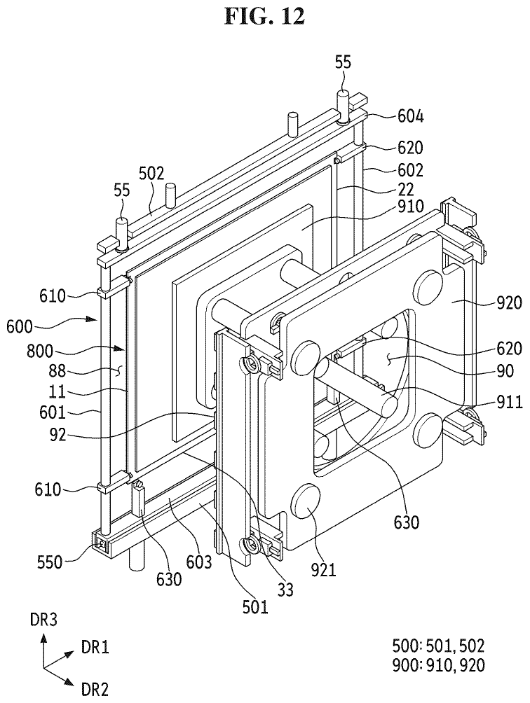

Next, as illustrated in FIG. 12, while the second magnet plate 800 is attached to the first driving mechanism 910, the pushers 55 may press the fourth carrier 600 in the third reverse direction to the distance of the second stage, and the lower track 501 may descend in the third reverse direction. Accordingly, a constraining force of support members 610, 620 and 630 of the fourth carrier 600 applied to the second magnet plate 800 may be removed. Therefore, the second magnet plate 800 may be maintained in a state where it can move in the second direction DR2 and the second reverse direction from the fourth carrier 600.

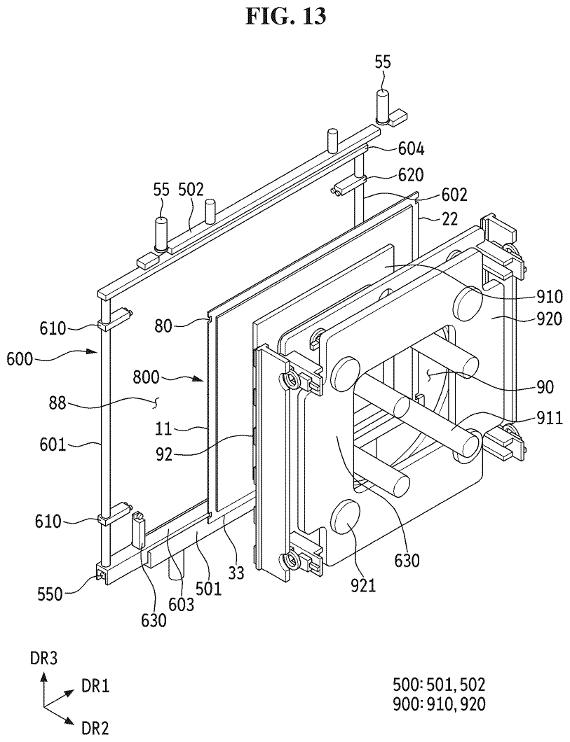

Next, as illustrated in FIG. 13, the first driving mechanism 910 may move along the second direction DR2. In other words, the first driving mechanism 910 may move toward the second inner wall 102 of the chamber 100 (or the second driving mechanism 920). Accordingly, the second magnet plate 800 attached to the first driving mechanism 910 may also move toward the second inner wall 102 of the chamber 100 (or the second driving mechanism 920). Therefore, the driving mechanism 900 and the second magnet plate 800 may be placed between the transport track 500 and the second inner wall 102 of the chamber 100.

Next, the fourth carrier 600 (e.g., the empty fourth carrier 600) which has transported the second magnet plate 800 may be unloaded from the chamber 100 through the second gate G2 of the chamber 100 along the transport track 500.

In this way, according to an embodiment, since the magnet plate 800 is detachably attached to the first driving mechanism 910, it can be easily replaced through the carrier 600.

The above magnet plate replacement operation may be performed, for example, after a deposition process on the substrate 50 is completed or before a series of deposition processes are performed on the substrate 50.

If an intermediate chamber for controlling the pressure of the chamber 100 is connected to the chamber 100, the operation of replacing the magnet plate 800 may be performed without a venting operation on the chamber 100. In this case, an operation rate of the deposition device can be improved.

According to a deposition device for a display device and a method of replacing a magnet plate of the deposition device according to an embodiment, the adhesion between a mask and a substrate can be effectively improved.

In addition, according to an embodiment, a magnet plate can be easily replaced through a carrier.

However, the effects of the present disclosure are not restricted to the one set forth herein. The above and other effects of the present disclosure will become more apparent to one of daily skill in the art to which the present disclosure pertains by referencing the claims.

The display device according to the embodiment can be applied to various electronic devices. The electronic device according to one embodiment includes the display device described above and may further include modules or devices having additional functions in addition to the display device.

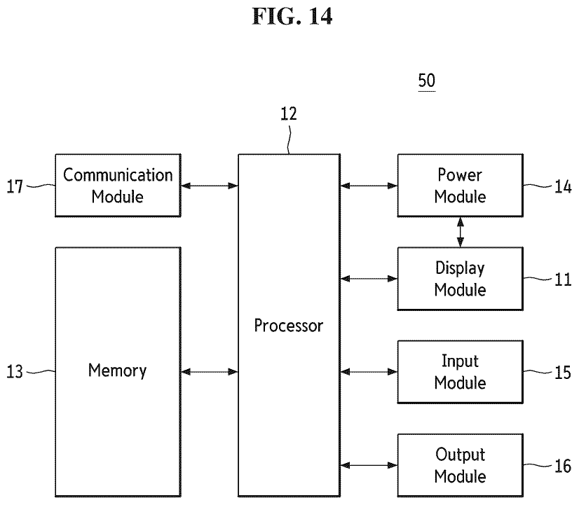

FIG. 14 is a block diagram of an electronic device according to one embodiment. Referring to FIG. 14, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

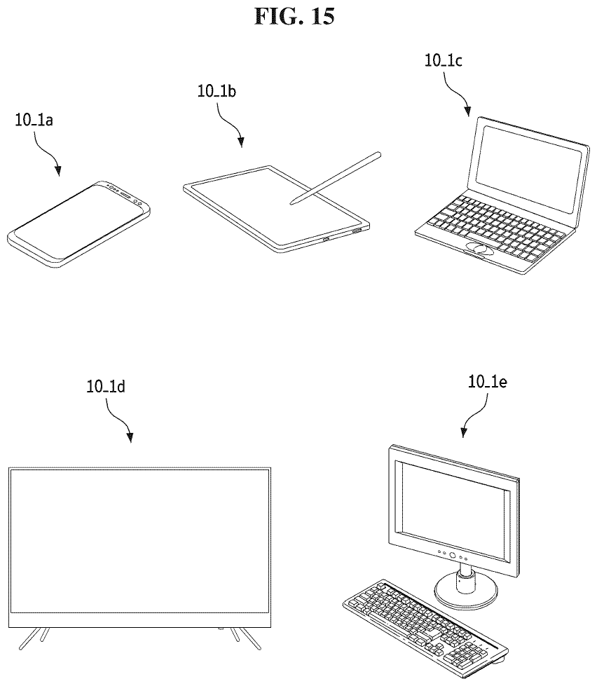

FIGS. 15, 16, and 17 are schematic diagrams of electronic devices according to various embodiments. FIGS. 15 to 17 illustrate examples of various electronic devices to which the display device according to the embodiments is applied.

FIG. 15 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

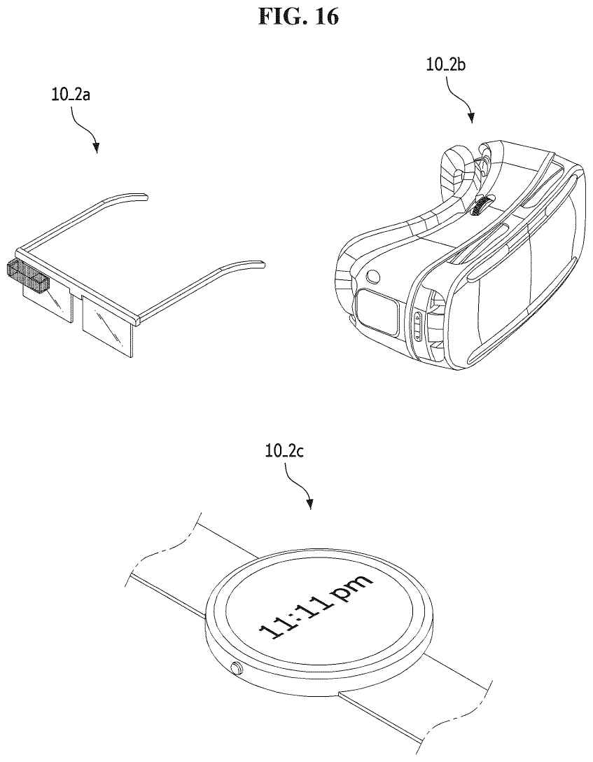

FIG. 16 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

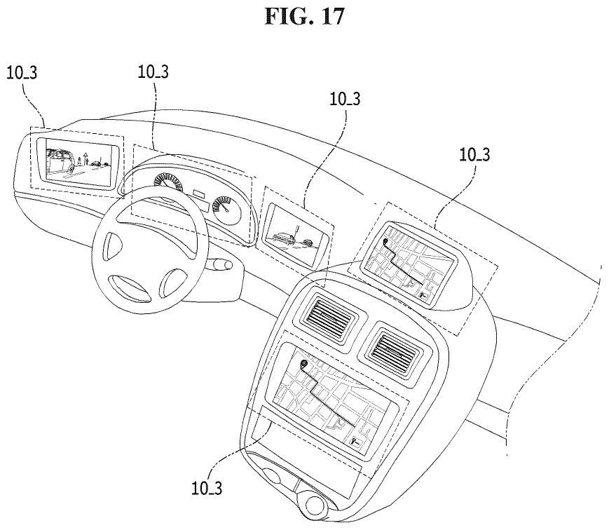

The smart watch 10_2c includes a biometric sensor as an input device, and may provide biometric information recognized by the biometric sensor to the user through the display module. FIG. 17 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A deposition device for a display device, the deposition device comprising:
a chamber;
a deposition source in the chamber;
a stage on the deposition source;
a mask structure on the stage;
a magnet plate on the mask structure; and
a first driving mechanism connected to the magnet plate,
wherein the magnet plate is detachably connected to the first driving mechanism.

2. The deposition device of claim 1, wherein the magnet plate is attached to a magnet of the first driving mechanism.

3. The deposition device of claim 2, wherein the magnet of the first driving mechanism comprises a permanent magnet.

4. The deposition device of claim 2, wherein the magnet plate comprises:
a base member;
a magnet on a first surface of the base member; and
a magnetic object disposed on a second surface of the base member, opposite to the first surface, and attached to the magnet of the first driving mechanism.

5. The deposition device of claim 1, further comprising a substrate tray disposed between the mask structure and the magnet plate.

6. The deposition device of claim 5, further comprising a second driving mechanism connected to the substrate tray.

7. The deposition device of claim 6, wherein the substrate tray is attached to an electro-permanent magnet of the second driving mechanism.

8. The deposition device of claim 7, wherein the substrate tray comprises a magnetic object attached to the electro-permanent magnet of the second driving mechanism.

9. The deposition device of claim 1, further comprising a transport track, which passes through a first gate of the chamber and a second gate of the chamber and is disposed inside the chamber and outside the chamber.

10. The deposition device of claim 9, further comprising a carrier movable along the transport track.

11. The deposition device of claim 10, wherein the transport track comprises:
a lower track; and
an upper track on the lower track.

12. The deposition device of claim 11, wherein the carrier is disposed between the lower track and the upper track.

13. The deposition device of claim 12, wherein the carrier comprises:
a first bar;
a second bar facing the first bar;
a third bar disposed on the lower track;
a fourth bar disposed under the upper track and facing the third bar;
a first support member extending from the first bar toward the second bar;
a second support member extending from the second bar toward the first bar; and
a third support member extending from the third bar toward the fourth bar,
wherein an opening is defined by the first bar, the second bar, the third bar, and the fourth bar.

14. The deposition device of claim 13, wherein the first support member comprises:
an extension portion extending from the first bar; and
a protrusion rotatably connected to an end portion of the extension portion.

15. The deposition device of claim 14, wherein the third support member comprises:
an extension portion extending from the third bar;
a protruding portion disposed on an end portion of the extension portion; and
a protrusion rotatably disposed on a side of the protruding portion.

16. The deposition device of claim 13, further comprising a pusher facing the fourth bar through an opening of the upper track and movable toward the fourth bar.

17. The deposition device of claim 13, wherein the carrier transports the magnet plate.

18. The deposition device of claim 17, wherein the magnet plate defines grooves on sides thereof, and
the grooves are disposed adjacent to the first support member and the second support member.

19. A method of replacing a magnet plate of a deposition device for a display device, the method comprising:
loading a first carrier into a chamber of the deposition device by moving the first carrier along a transport track of the deposition device, wherein the first carriers includes support members;
lowering the first carrier by pressing the first carrier with a pusher disposed on the transport track;
placing a first magnet plate attached to a driving mechanism of the deposition device in an opening of the first carrier;
raising the first carrier by moving the pusher to an original position to support the first magnet plate and load the first magnet plate onto the first carrier;
separating the first magnet plate loaded on the first carrier from the driving mechanism;
unloading the first carrier loaded with the first magnet plate from the chamber by moving the first carrier along the transport track;
loading a second carrier loaded with a second magnet plate into the chamber by moving the second carrier along the transport track;
attaching the driving mechanism and the second magnet plate to each other;
releasing a constraining force of support members of the second carrier applied to the second magnet plate by lowering the second carrier by pressing the second carrier with the pusher;
separating the second magnet plate from the second carrier by moving the driving mechanism to which the second magnet plate is attached; and
unloading the second carrier from the chamber by moving the second carrier along the transport track.

20. An electronic device comprising:
a display device,
wherein a deposition device which deposits a deposition material to a substrate of the display device includes:
a chamber;
a deposition source in the chamber;
a stage on the deposition source;
a mask structure on the stage;
a magnet plate on the mask structure; and
a first driving mechanism connected to the magnet plate,
wherein the magnet plate is detachably connected to the first driving mechanism.
